(19) United States
(12) Patent Application Publication
(10) Pub. No.: US 2013/0297244 A1
(43) Pub. Date: Nov. 7, 2013

(54) SECONDARY BATTERY LIFETIME PREDICTION APPARATUS, BATTERY SYSTEM AND SECONDARY BATTERY LIFETIME PREDICTION METHOD

(71) Applicant: Hideyasu Takatsuji, Tokyo (JP)

(72) Inventor: Hideyasu Takatsuji, Tokyo (JP)

(73) Assignee: MITSUBISHI HEAVY INDUSTRIES, LTD., Tokyo (JP)

(21) Appl. No.: 13/979,777

(22) PCT Filed: Feb. 17, 2011
(86) PCT No.: PCT/JP2012/053878

§ 371 Date: Jul. 15, 2013

(30) Foreign Application Priority Data
Feb. 28, 2011 (JP) 2011-043260

(51) Int. Cl. G01R 31/36

(52) U.S. Cl. CPC G01R 31/3679
USPC 702/63

(57) ABSTRACT

An object of the present invention is to provide a secondary battery lifetime prediction apparatus, a battery system and a secondary battery lifetime prediction method that allow a more accurate lifetime prediction for a secondary battery. The battery system (10) includes a secondary battery (28) that supplies power to an electric power load (18) and an ammeter (32) and a thermometer (34) that measure the level of a factor affecting the degradation of the secondary battery (28), compares the peak value of a history distribution based on a use frequency of the secondary battery (28) depending on the level of the factor that is measured multiple times in a predetermined period by the ammeter (32) and the thermometer (34) with the peak value of an ideal distribution based on a previously estimated use frequency of the secondary battery (28) depending on the level of the factor, derives a degree of the degradation of the secondary battery (28) in use based on the comparison result and a previously estimated degree of the degradation of the secondary battery (28), and predicts the lifetime of the secondary battery (28) based on the degree of the degradation derived.

### TECHNICAL FIELD

The present invention relates to a secondary battery lifetime prediction apparatus, a battery system and a secondary battery lifetime prediction method.

### BACKGROUND ART {0002}

A secondary battery degrades due to repeated charging and discharging, use in high temperature environment or the like, and therefore has a usable period (lifetime).

Patent Literature 1 discloses a technique for predicting the lifetime of a secondary battery. In the technique, the resistance value of a power storage unit in the secondary battery is calculated from the internal resistance value of the secondary battery, and the increasing rate of the resistance value of the power storage unit in use environment of the secondary battery is calculated. Then, the remaining lifetime of the secondary battery is estimated from the calculated resistance value of the power storage unit and the calculated increasing rate of the resistance value of the power storage unit.

### CITATION LIST

### Patent Literature

### {PTL 1}

Japanese Unexamined Patent Application, Publication No. 2010-139260

### SUMMARY OF INVENTION

### Technical Problem

In the technique described in Patent Literature 1, before the estimation of the remaining lifetime of the secondary battery, the internal resistance value of the secondary battery is calculated from an electric current change value and a voltage change value of the secondary battery, which are obtained by a real-time measurement of the electric current and voltage. Therefore, there is a possibility that a measurement error of the electric current and voltage causes a sudden decrease or increase of the remaining lifetime of the secondary battery.

The present invention has been achieved in view of such a circumstance, and has an object to provide a secondary battery lifetime prediction apparatus, a battery system and a secondary battery lifetime prediction method that allow a more accurate lifetime prediction for a secondary battery.

### Solution to Problem

In order to solve the above problem, a secondary battery lifetime prediction apparatus, a battery system and a secondary battery lifetime prediction method according to the present invention adopt the following solutions.

A secondary battery lifetime prediction apparatus according to a first aspect of the present invention includes a measuring section for measuring level of a factor, the factor affecting degradation of a secondary battery; a comparing section for comparing a first value based on a use frequency of the secondary battery depending on the level of the factor measured by the measuring section with a second value based on a previously estimated use frequency of the secondary battery depending on the level of the factor, the level of the factor being measured multiple times in a predetermined period by the measuring section; a deriving section for deriving a degree of the degradation of the secondary battery in use, based on a comparison result by the comparing section and a previously estimated degree of the degradation of the secondary battery; and a predicting section for predicting a lifetime of the secondary battery, based on the degree derived by the deriving section.

In accordance with the first aspect of the present invention, the measuring section measures the level of the factor affecting the degradation of the secondary battery. Examples of the factor affecting the degradation of the secondary battery include the electric current of the secondary battery, the stored charge amount of the secondary battery and the temperature of the secondary battery.

In the first aspect of the present invention, the use frequency of the secondary battery depending on the level of the factor that is measured multiple times in the predetermined period, in other words, a use history of the secondary battery, is determined. Examples of the above predetermined period include a period from the beginning of use of the secondary battery to the present time. For example, the factor is measured ten times a day. Increasing the period and the number of times of the factor measurement by the measuring section leads to a further highly accurate lifetime prediction for the secondary battery.

The comparing section compares the first value based on the use frequency of the secondary battery depending on the level of the factor that is measured multiple times in the predetermined period by the measuring section, with the second value based on the previously estimated use frequency of the secondary battery depending on the level of the factor.

That is to say, the first value is a value corresponding to an actual use condition of the secondary battery because the first value is based on actually measured values of the factor, and the second value is a value corresponding to an ideal use condition that is determined from design values of the secondary battery. Therefore, the comparison between the first value and the second value represents a comparison between the actual use condition of the secondary battery and the ideal use condition of the secondary battery.

The deriving section derives the degree of the degradation of the secondary battery in use, based on the comparison result by the comparing section and the previously estimated degree of the degradation of the secondary battery. The previously estimated degree of the degradation of the secondary battery is determined, for example, by previously performing experiments. Then, the predicting section predicts the lifetime of the secondary battery, based on the degree derived by the deriving section.

Thus, in the first aspect of the present invention, the level of the factor affecting the degradation of the secondary battery is measured multiple times in the predetermined period, and the lifetime of the secondary battery is predicted based on the use frequency of the secondary battery depending on the level of the factor measured. Therefore, it is possible to provide a more accurate lifetime prediction for the secondary battery.

In the secondary battery lifetime prediction apparatus according to the first aspect of the present invention, the deriving section may derive the degree of the degradation of the secondary battery in such a manner that the degree of the degradation becomes larger in response to a frequency at which the level of the factor measured by the measuring section exceeds a predetermined threshold.

When the level of the factor affecting degradation of the secondary battery exceeds a certain threshold, the degradation of the secondary battery is accelerated. For this reason, since the secondary battery lifetime prediction apparatus according to the first aspect of the present invention derives the degree of the degradation of the secondary battery in such a manner that the degree of the degradation becomes larger in response to the frequency at which the level of the factor measured by the measuring section exceeds the predetermined threshold, it is possible to provide a more accurate lifetime prediction for the secondary battery.

The secondary battery lifetime prediction apparatus according to the first aspect of the present invention may further include a control section for controlling a use condition of the secondary battery such that a deviation amount between the first value and the second value becomes small.

In accordance with the first aspect of the present invention, the control section controls a use condition of the secondary battery such that the deviation amount between the first value and the second value becomes small. This allows the degree of the degradation of the secondary battery to be equal to an ideal degradation, and facilitates the management of the lifetime of the secondary battery.

In the secondary battery lifetime prediction apparatus according to the first aspect of the present invention, the deriving section may derive the degree of the degradation of the secondary battery in use by multiplying the previously estimated degree of the degradation and the deviation amount between the first value and the second value.

In accordance with the first aspect of the present invention, the degree of the degradation is previously estimated. This estimated degree of the degradation is determined, for example, by previously performing experiments. Then, the secondary battery lifetime prediction apparatus according to the first aspect of the present invention derives the degree of the degradation of the secondary battery in use by multiplying the previously estimated degree of the degradation and the deviation amount between the first value and the second value. Therefore, it is possible to easily provide a more accurate lifetime prediction for the secondary battery.

In the secondary battery lifetime prediction apparatus according to the first aspect of the present invention, the deriving section may predict the lifetime of the secondary battery from at least one of a change in the battery capacity of the secondary battery and a change in the internal resistance of the secondary battery. The change in the battery capacity and the change in the internal resistance are based on the degree derived by the deriving section.

As the secondary battery degrades, the battery capacity of the secondary battery decreases while the internal resistance of the secondary battery increases. For this reason, in accordance with the first aspect of the present invention, it is possible to provide a more accurate lifetime prediction for the secondary battery, by means of predicting the lifetime of the secondary battery from at least one of the change in the battery capacity of the secondary battery and the change in the internal resistance of the secondary battery that are based on the degree of the degradation of the secondary battery in use.

In the secondary battery lifetime prediction apparatus according to the first aspect of the present invention, the factor may be at least one of the electric current of the secondary battery, the stored charge amount of the secondary battery and the temperature of the secondary battery.

In accordance with the first aspect of the present invention, since the electric current, stored charge amount and temperature of the secondary battery can be easily measured, it is possible to easily provide a more accurate lifetime prediction for the secondary battery.

A battery system according to a second aspect of the present invention includes a secondary battery supplying power to a load, and the secondary battery lifetime prediction apparatus according to the first aspect of the present invention that predicts the lifetime of the secondary battery.

In accordance with the second aspect of the present invention, since the battery system includes the secondary battery supplying power to the load and the above described secondary battery lifetime prediction apparatus that predicts the lifetime of the secondary battery, it is possible to provide a more accurate lifetime prediction for the secondary battery.

A secondary battery lifetime prediction method according to a third aspect of the present invention includes a first stage of comparing a first value based on a use frequency of a secondary battery depending on level of a factor measured by a measuring section with a second value based on a previously estimated use frequency of the secondary battery depending on the level of the factor, the factor affecting degradation of the secondary battery, the level of the factor being measured multiple times in a predetermined period by the measuring section; a second stage of deriving a degree of the degradation of the secondary battery in use, based on a comparison result by the first stage and a previously estimated degree of the degradation of the secondary battery; and a third stage of predicting a lifetime of the secondary battery, based on the degree derived by the second stage.

In accordance with the third aspect of the present invention, the level of the factor affecting the degradation of the secondary battery is measured multiple times in the predetermined period, and the lifetime of the secondary battery is predicted based on the use frequency of the secondary battery depending on the level of the factor measured. Therefore, it is possible to provide a more accurate lifetime prediction for the secondary battery.

### Advantageous Effects of Invention

The present invention has an advantageous effect that a more accurate lifetime prediction for a secondary battery is possible.

### BRIEF DESCRIPTION OF DRAWINGS

FIG. 1 is a block diagram showing a configuration of a battery system according to an embodiment of the present invention.

FIG. 2 is a graph showing a relationship between the stored charge amount and the electromotive force of the secondary battery according to the embodiment of the present invention.

FIG. 3 are distribution charts showing a factor affecting the degradation of the secondary battery according to the embodiment of the present invention and a use frequency of the secondary battery, where FIG. 3(A) is a distribution chart when the factor is electric current, FIG. 3(B) is a distribution chart when the factor is stored charge amount, and FIG. 3(C) is a distribution chart when the factor is temperature.

FIG. 4 is a flowchart showing a processing of a secondary battery lifetime prediction program according to the embodiment of the present invention.

FIG. 5 are graphs showing a decreasing rate of the battery capacity of the secondary battery according to the embodiment of the present invention, where FIG. 5(A) shows a decreasing rate of the battery capacity depending on electric current, FIG. 5(B) shows a decreasing rate of the battery capacity depending on stored charge amount, and FIG. 5(C) shows a decreasing rate of the battery capacity depending on temperature.

FIG. 6 is a distribution chart showing an example of a history distribution when the level of a factor measured exceeds a threshold at which the degradation of the secondary battery according to the embodiment of the present invention is accelerated.

FIG. 7 are graphs showing a changing rate of the internal resistance of the secondary battery according to the embodiment of the present invention, where FIG. 7(A) shows a changing rate of the internal resistance depending on electric current, FIG. 7(B) shows a changing rate of the internal resistance depending on stored charge amount, and FIG. 7(C) shows a changing rate of the internal resistance depending on temperature.

FIG. 8 are graphs showing a result of lifetime prediction for the secondary battery according to the embodiment of the present invention, where FIG. 8(A) shows a result of the lifetime prediction from a change of the battery capacity of the secondary battery, and FIG. 8(B) shows a result of the lifetime prediction from a change of the internal resistance of the secondary battery.

### DESCRIPTION OF EMBODIMENTS

An embodiment of a secondary battery lifetime prediction apparatus, a battery system and a secondary battery lifetime prediction method according to the present invention will be described below with reference to the drawings.

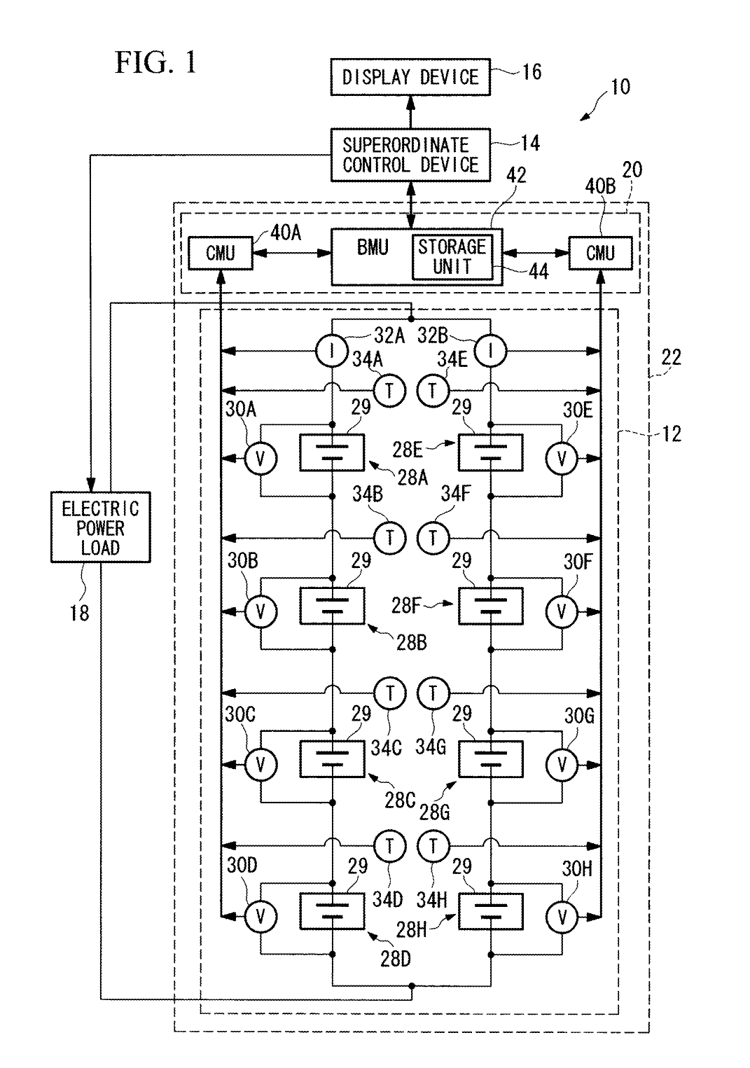

FIG. 1 is a block diagram showing a configuration of a battery system 10 according to the embodiment.

The battery system 10 according to the embodiment, which is a system in which power is charged and discharged by secondary batteries, for example is installed in an electric vehicle and is used to supply power thereto. Besides the electric vehicle, the battery system 10 may be used to supply power to other moving vehicles, as exemplified by an industrial vehicle such as a forklift, an electric train, a ship, an aircraft and a spacecraft. Also, the battery system 10 may be used in, for example, a household power storage system, and a power grid stabilization system that is combined with a power generator utilizing natural energy such as a wind turbine generator and a solar photovoltaic generator.

The battery system 10 according to the embodiment includes an assembled battery 12, a superordinate control device 14, a display device 16, an electric power load 18, and a battery management system (BMS) 20. The assembled battery 12 and the BMS 20 constitute a battery module 22, which is replaceable in the battery system 10.

The assembled battery 12 includes plural secondary batteries 28A to 28F (in the embodiment, lithium-ion battery as an example) that are connected to each other, and supplies power to the electric power load 18. In the following description, if the secondary batteries 28 are distinguished from each other, any one of characters A to F is put to the end of the reference numeral. If the secondary batteries 28 are not distinguished from each other, the characters A to F are omitted.

The secondary batteries 28 each include a battery case 29 that is composed of an aluminum-based material. In the interior of the battery case 29, which is a hollow cube-shaped case, a positive electrode and a negative electrode are placed, and non-aqueous electrolyte containing lithium-ion is pooled.

In the embodiment, as shown in FIG. 1, the secondary batteries 28A to 28D are connected in series, and the secondary batteries 28E to 28H are connected in series. Furthermore, the in-series-connected secondary batteries 28A to 28D and the in-series-connected secondary batteries 28E to 28H are connected in parallel. The number and connection configuration of the secondary batteries 28 shown in FIG. 1 are just one example. It is allowable to connect the plural secondary batteries 28 to each other only in series or only in parallel.

As shown in FIG. 1, the secondary batteries 28 are each connected to voltmeters 30A to 30H that measure the voltage between the positive electrode terminal and the negative electrode terminal of the secondary battery 28.

The assembled battery 12 is equipped with an ammeter 32A that measures the electric current on the pathway along which the secondary batteries 28A to 28D are connected in series, and an ammeter 32B that measures the electric current on the pathway along which the secondary batteries 28E to 28H are connected in series.

In addition, the assembled battery 12 is equipped with thermometers 34A to 34H each of which measures the surface temperature of the battery case 29 of the corresponding secondary battery 28. In the present invention, thermocouples are used as the thermometers 34A to 34H. Besides thermocouples, other thermometers such as a resistance bulb may be used. Also, the thermometers 34A to 34H may measure the temperature at a point near the corresponding battery case 29 instead of the surface temperature of the corresponding battery case 29.

The voltage values measured by the voltmeters 30A to 30H, the electric current values measured by the ammeters 32A, 32B, and the temperature values measured by the thermometers 34A to 34H are transmitted to the BMS 20.

In the following description, if the voltmeters 30 or the thermometers 34 are distinguished from each other, any one of characters A to F is put to the end of the reference numeral. If the voltmeters 30 or the thermometers 34 are not distinguished from each other, the characters A to F are omitted. Also, in the following description, if the ammeters 32 are distinguished from each other, any one of characters A and B is put to the end of the reference numeral. If the ammeters 32 are not distinguished from each other, the characters A and B are omitted.

The BMS 20 includes cell monitor units (CMU) 40A, 40B, and a battery management unit (BMU) 42.

The CMU 40A is connected to the voltmeters 30A to 30D, the ammeter 32A and the thermometers 34A to 34D, and thereby receives their measured values. The CMU 40B is connected to the voltmeters 30E to 30H, the ammeter 32B and the thermometers 34E to 34H, and thereby receives their measured values.

The CMUs 40A, 40B each include an analog digital converter (ADC), which is not shown in the figure. The CMUs 40A, 40B convert the measured values by the voltmeters 30, ammeter 32 and thermometers 34, which are analog signals, into digital signals, and transmit the digital signals to the BMU 42. Although the BMS 20 includes two CMUs 40A, 40B in the embodiment, the BMS 20 may include a single CMU, or, three or more CMUs. In the case of a single CMU, all the measured values are input to the single CMU, and in the case of three or more CMUs, the measured values are distributed to be input to the corresponding CMUs.

The BMU 42, based on the digitized measured values input from the CMUs 40A, 40B, executes a secondary battery lifetime prediction processing, which will be described later, and transmits the processing result to the superordinate control device 14. The BMU 42 includes a storage unit 44 that stores a secondary battery lifetime prediction program, which will be described later, the measured values input from the CMUs 40A, 40B, and other various information.

The superordinate control device 14 controls the electric power load 18 in response to a user's instruction (for example, an extent to which the user presses an accelerator), and receives information associated with the assembled battery 12 from the BMS 20. Such associated information includes the measured values by the voltmeters 30, ammeters 32 and thermometers 34, the stored charge amount of each secondary battery 28 calculated in the BMS 20, and a result of the secondary battery lifetime prediction processing, which will be described later. The superordinate control device 14 is connected to the display device 16, and provides various notices to the user therethrough, for example, by displaying an image on the screen of the display device 16 based on a variety of information such as the above associated information.

The display device 16 is, for example, a monitor such as a liquid crystal panel having an acoustic system, and is controlled by the superordinate control device 14 to provide various notices to the user.

The electric power load 18 is, for example, a power conversion device, as exemplified by an electric motor whose rotating shaft is mechanically linked to the axle of an electric vehicle, an electric motor for driving a windshield wiper, and an inverter.

Here, the secondary battery 28 degrades due to repeated charging and discharging, use in high temperature environment or the like. Then, when the secondary battery 28 reaches the end of the lifetime, the secondary battery 28 cannot be used anymore. Examples of factors affecting such degradation of the secondary batteries 28 include the electric current, stored charge amount and temperature of the secondary battery 28.

Accordingly, in the battery system 10 according to the embodiment, the secondary battery lifetime prediction processing for predicting the lifetime of the secondary battery 28 is executed, based on the factors affecting the degradation of the secondary battery 28.

In the execution of the secondary battery lifetime prediction processing, the battery system 10 according to the embodiment sequentially stores electric current values measured by the ammeters 32 and temperature values measured by the thermometers 34 through the CMUs 40A, 40B into the storage unit 44 of the BMU 42.

The stored charge amount of the secondary battery 28 also is stored into the storage unit 44 of the BMU 42.

Here, the stored charge amount of the secondary battery 28 is calculated from the electric current values measured by the ammeters 32, by the following Formulas (1), (2). In the following formulas, SOC (State Of Charge) represents a stored charge amount, Q₀ represents an initial battery capacity of the secondary battery 28, ΔQ represents an amount of change in the battery capacity of the secondary battery 28, and I represents an electric current of the secondary battery 28.

$$\begin{matrix}\{ Formula 1 \} & \\ SOC = \frac{Δ Q}{{Q}_{0}} \times 100 ( \% ) & ( 1 ) \\ \{ Formula 2 \} & \\ Δ Q = \int I d t & ( 2 )\end{matrix}$$

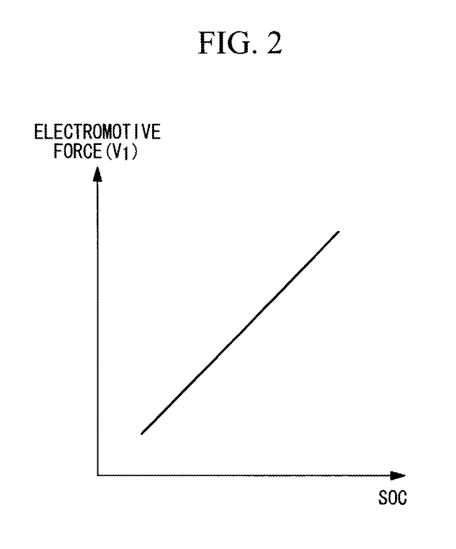

The electromotive force and stored charge amount of the secondary battery 28 have a one-to-one proportional relationship shown in FIG. 2. The electromotive force V₁ and voltage V₀ of the secondary battery 28 have a relationship shown in the following Formula (3), where R represents an internal resistance.

### {Formula 3}

V₁=V₀−IR (3)

Accordingly, it is desirable that the BMU 42 should properly compensate the stored charge amount determined by Formulas (1), (2) using the electromotive force determined by Formula (3) such that the stored charge amount and the electromotive force have a one-to-one relationship. As the electromotive force V₁, the voltage value measured by the voltmeter 30 disposed for each secondary battery 28 is used. Alternatively, it is allowable to dispose a voltmeter at the side of the electric power load 18 and to use the voltage value measured by this voltmeter.

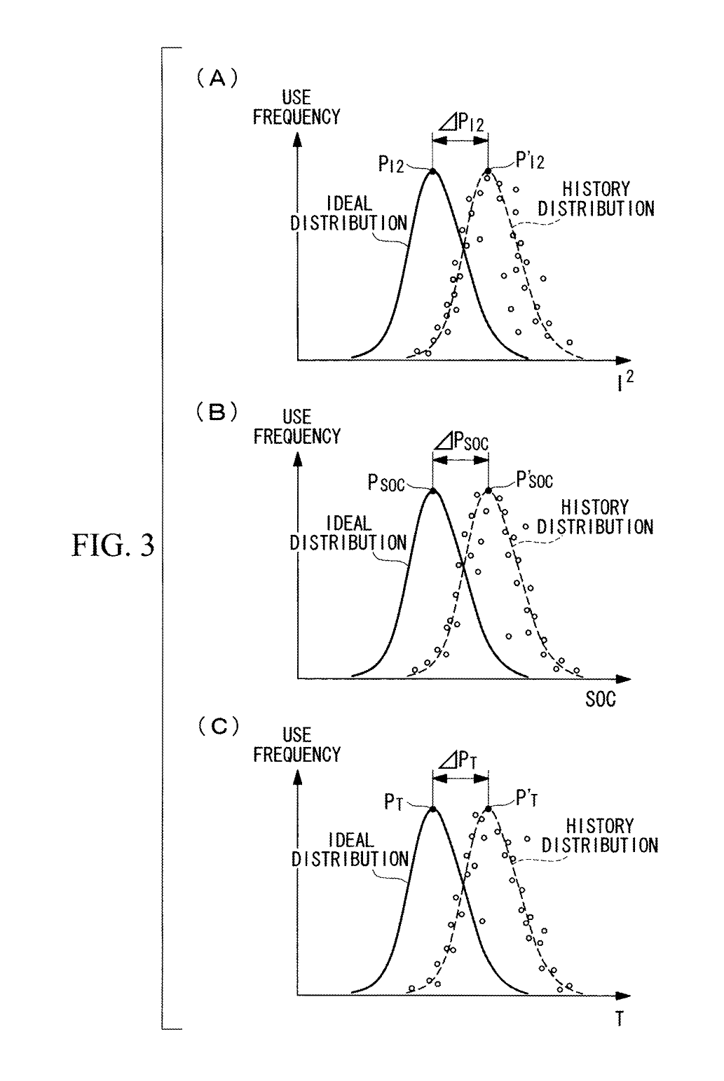

The BMU 42 according to the embodiment determines use frequencies of the secondary battery 28 depending on the level of the factors that are measured multiple times in a predetermined period, in other words, use histories of the secondary battery 28. FIG. 3 are distribution charts showing the use history relevant to the measured factor and the use frequency of the secondary battery 28, where FIG. 3(A) is a distribution chart when the factor is electric current, FIG. 3(B) is a distribution chart when the factor is stored charge amount, and FIG. 3(C) is a distribution chart when the factor is temperature.

In the embodiment, the above predetermined period is, for example, a period from the beginning of use of the secondary battery 28 to the present time. The factor is measured, for example, ten times a day. In the secondary battery lifetime prediction processing according to the embodiment, increasing the period and number of times of the factor measurement leads to a further highly accurate lifetime prediction for the secondary battery.

In FIGS. 3(A) to 3(C), the broken line shows a distribution based on the factor measured actually, (hereinafter, referred to as a “history distribution”), that is, a distribution relevant to the factor corresponding to an actual use condition of the secondary battery 28. On the other hand, the full line shows a distribution relevant to a relationship between the factor and a use frequency corresponding to an ideal use condition that is determined from design values of the secondary battery 28, (hereinafter, referred to as an “ideal distribution”). Thus, whenever the level of the electric current, stored charge amount or temperature of the secondary battery 28, which is a factor, is measured and stored in the storage unit 44, use frequency data at the level of the factor are added. Therefore, the history distribution varies in real time. In contrast, the ideal distribution does not vary.

As shown in FIG. 3(A), in the history distribution relevant to the electric current of the secondary battery 28, the square of the electric current is taken as the abscissa, in order to eliminate the difference between charging and discharging, both of which cause the degradation of the secondary battery 28.

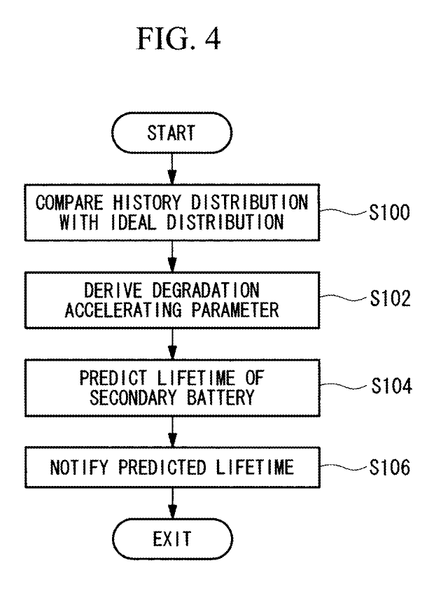

FIG. 4 is a flowchart showing a processing of the secondary battery lifetime prediction program that is executed by the BMU 42 at the secondary battery lifetime prediction processing. This secondary battery lifetime prediction program is previously stored at a predetermined area in the storage unit 44. This program may be executed when a start instruction for the secondary battery lifetime prediction processing is input through an operation unit, not shown in the figure, by the user (administrator) of the battery system 10. Alternatively, this program may be executed at a predetermined time interval.

Firstly, in stage 100 shown in FIG. 4, the history distribution is compared with the ideal distribution.

More exactly, the peak value P of the ideal distribution is extracted as a representative value of the ideal distribution, and the peak value P′ of the history distribution is extracted as a representative value of the history distribution.

Then, a deviation amount ΔP between the peak value P of the ideal distribution and the peak value P′ of the history distribution is derived. The respective deviation amounts for the factors are determined by the following Formulas (4) to (6).

The following Formula (4) shows the deviation amount ΔP₁₂ for the electric current of the secondary battery 28, where P₁₂ represents the peak value of the ideal distribution, and P′₁₂ represents the peak value of the history distribution.

$$\begin{matrix}\{ Formula 4 \} & \\ Δ {P}_{I 2} = \frac{{P}_{I 2}^{′}}{{P}_{I 2}} & ( 4 )\end{matrix}$$

The following Formula (5) shows the deviation amount ΔP_{SOC} for the stored charge amount of the secondary battery 28, where P_{SOC} represents the peak value of the ideal distribution, and P′_{SOC} represents the peak value of the history distribution.

$$\begin{matrix}\{ Formula 5 \} & \\ Δ {P}_{SOC} = \frac{{P}_{SOC}^{′}}{{P}_{SOC}} & ( 5 )\end{matrix}$$

The following Formula (6) shows the deviation amount ΔP_{T} for the temperature of the secondary battery 28, where P_{T} represents the peak value of the ideal distribution, and P′_{T} represents the peak value of the history distribution.

$$\begin{matrix}\{ Formula 6 \} & \\ Δ {P}_{T} = \frac{{P}_{T}^{′}}{{P}_{T}} & ( 6 )\end{matrix}$$

In the subsequent stage 102, a degradation accelerating parameter, which represents a degree of the degradation of the secondary battery 28 in use, is derived based on both the deviation amount ΔP, which is a comparison result in stage 100, and a previously estimated degree of the degradation of the secondary battery 28.

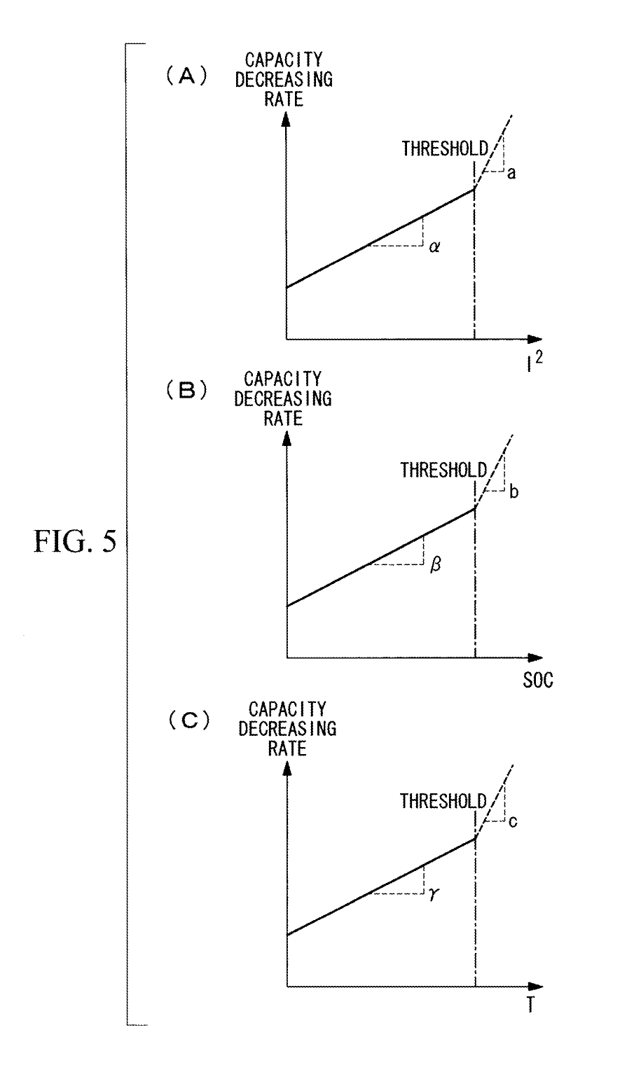

For example, the previously estimated degree of the degradation of the secondary battery 28 is the slopes α, β and γ shown in FIGS. 5(A) to 5(C), which are the slopes of the decreasing rates of the battery capacity (hereinafter, referred to as “capacity decreasing rates”) depending on the electric current, stored charge amount and temperature of the secondary battery 28. FIG. 5(A) shows the capacity decreasing rate depending on the electric current of the secondary battery 28, FIG. 5(B) shows the capacity decreasing rate depending on the stored charge amount of the secondary battery 28, and FIG. 5(C) shows the capacity decreasing rate depending on the temperature of the secondary battery 28. The capacity decreasing rates are determined, for example, by previously performing experiments.

In this stage, as shown in the following Formula (7), the degradation accelerating parameter K of the secondary battery 28 in use is derived from the values resulting from multiplying the slopes α, β and γ of the capacity decreasing rates depending on the factors and the deviation amounts ΔP_{I2}, ΔP_{SOC} and ΔP_{T} for the factors, respectively.

### {Formula 7}

K=α·ΔP_{I2}+β·ΔP_{SOC}+γ·ΔP_{T} (7)

As shown in FIGS. 5(A) to 5(C), when the level of the factor exceeds a predetermined threshold, the capacity decreasing rate becomes large compared to that at the level below the threshold (slope α<slope a, slope β<slope b, slope γ<slope c). For example, in lithium-ion batteries, the level of the factor exceeding the threshold causes a leak of non-aqueous electrolyte containing lithium-ion from the battery case 29, resulting in an acceleration of the degradation of the secondary battery 28.

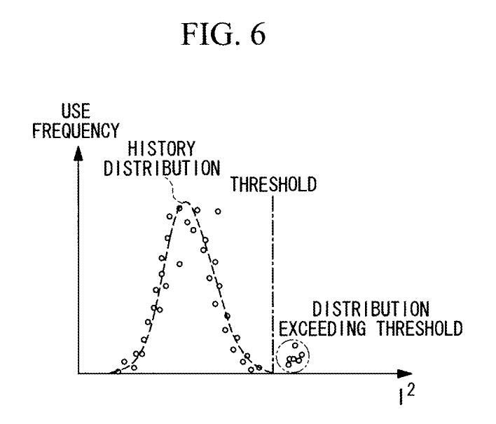

Accordingly, as an example shown in FIG. 6, the battery system 10 according to the embodiment detects a use frequency (the number of times) at which the level of the factor exceeds the threshold, for each factor. Then, as shown in the following Formula (8), the battery system 10 derives the degradation accelerating parameter K in such a manner that it becomes larger in response to the number of times that the level of the factor has exceeded the threshold.

### {Formula 8}

K=α·ΔP_{I2}+β·ΔP_{SOC}+γ·ΔP_{T}+A·N_{I2}+B·N_{SOC}+C+N_{T} (8)

In Formula (8), A represents a sensitivity of the degree of the degradation to the number of times that the level of the electric current of the secondary battery 28 exceeds the threshold; B represents a sensitivity of the degree of the degradation to the number of times that the level of the stored charge amount of the secondary battery 28 exceeds the threshold; C represents a sensitivity of the degree of the degradation to the number of times that the level of the temperature of the secondary battery 28 exceeds the threshold; N_{I2} represents the number of times that the level of the electric current of the secondary battery 28 exceeds the threshold; N_{SOC} represents the number of times that the level of the stored charge amount of the secondary battery 28 exceeds the threshold; and N_{T} represents the number of times that the level of the temperature of the secondary battery 28 exceeds the threshold. The values of the sensitivities A, B and C are determined, for example, by previously performing experiments.

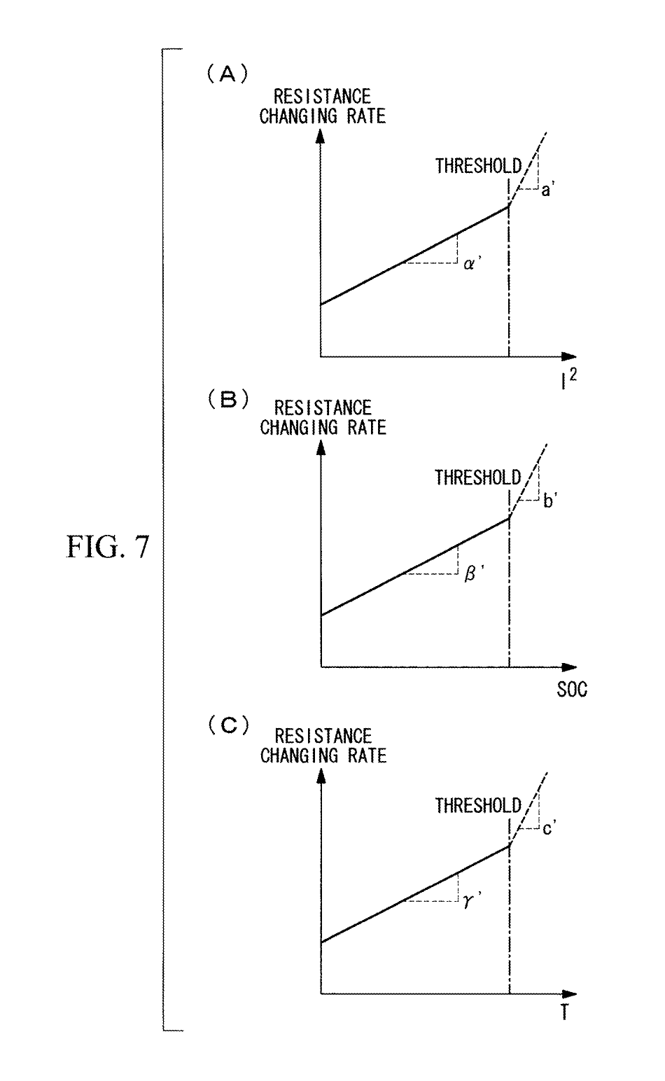

In the embodiment, another degradation accelerating parameter K′ also is derived as the previously estimated degree of the degradation of the secondary battery 28. The degradation accelerating parameter K′ is obtained from the slopes α′, β′ and γ′ shown in FIGS. 7(A) to 7(C), which are the slopes of the changing rates of the internal resistance (hereinafter, referred to as “resistance changing rates”) depending on the electric current, stored charge amount and temperature of the secondary battery 28.

In this stage, as shown in the following Formula (9), the degradation accelerating parameter K′ of the secondary battery 28 in use is derived from the values resulting from multiplying the slopes α′, β′ and γ′ of the resistance changing rates depending on the factors and the deviation amounts for the factors, respectively.

### {Formula 9}

K′=α′·ΔP_{I2}+β′·ΔP_{SOC}+γ′·ΔP_{T} (9)

Similar to the capacity changing rate, as shown in FIGS. 7(A) to 7(C), when the level of the factor exceeds a predetermined threshold, the resistance changing rate becomes large compared to the decreasing rate of the internal resistance at the level below the threshold (slope α′<slope a′, slope β′<slope b′, slope γ′<slope c′).

Accordingly, similar to the above, the battery system 10 according to the embodiment detects a use frequency (the number of times) at which the level of the factor exceeds the threshold, for each factor. Then, as shown in the following Formula (10), the battery system 10 derives the degradation accelerating parameter K′ in such a manner that it becomes larger in response to the number of times that the level of the factor has exceeded the threshold.

### {Formula 10}

K′=α′·ΔP_{I2}+β′·ΔP_{SOC}+γ′·ΔP_{T}+A′·N_{I2}+B′·N_{SOC}+C′+N_{T} (10)

In Formula (10), A′ represents a sensitivity of the degree of the degradation to the number of times that the level of the electric current of the secondary battery 28 exceeds the threshold; B′ represents a sensitivity of the degree of the degradation to the number of times that the level of the stored charge amount of the secondary battery 28 exceeds the threshold; and C′ represents a sensitivity of the degree of the degradation to the number of times that the level of the temperature of the secondary battery 28 exceeds the threshold. The values of the sensitivities A′, B′ and C′ are determined, for example, by previously performing experiments.

The slopes α, β, γ, α′, β′ and γ′, and the sensitivities A, B, C, A′, B′ and C′ may be weighted. The weights vary, for example, according to use environment of the battery system 10. For example, high temperature accelerates the degradation of the secondary battery 28. Therefore, the slopes γ and γ′, and sensitivities C and C′ for temperature are preferably weighted so as to have a greater effect on the degradation accelerating parameters K and K′.

In stage 104 shown in FIG. 4, the lifetime of the secondary battery 28 is predicted based on the degradation accelerating parameters K and K′ derived in stage 102. In the embodiment, the lifetime of the secondary battery 28 is predicted from both a change in the battery capacity of the secondary battery 28 and a change in the internal resistance of the secondary battery 28.

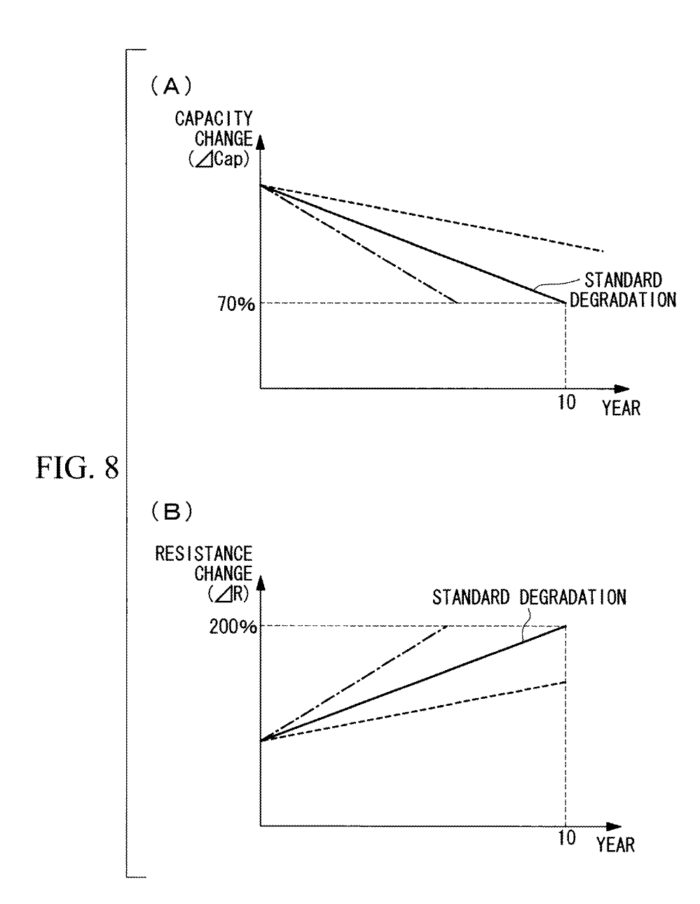

FIG. 8 are graphs showing results of lifetime prediction for the secondary battery 28, where FIG. 8(A) shows a result of the lifetime prediction based on a change of the battery capacity (hereinafter, referred to as a “capacity change”) of the secondary battery 28. The capacity change ΔCap is calculated by the following Formula (11), where Cap represents an initial value of the battery capacity of the secondary battery 28. The battery capacity of the secondary battery 28 decreases as the secondary battery 28 degrades.

### {Formula 11}

ΔCap=−K·Cap (11)

In FIG. 8(A), the full line shows a case that the peak values of the history distributions accord with the peak values of the ideal distributions, namely, a case that the deviation amount ΔP_{I2}=1; the deviation amount ΔP_{SOC}=1; the deviation amount ΔP_{T}=1; and the degradation accelerating parameter K=α+β+γ, (hereinafter, the case is referred to as a “standard degradation”). In the embodiment, the lifetime of the secondary battery 28 is defined as the number of years after which the capacity change will reach a judgment value. The judgment value is a value by which the capacity change is judged to reach the end of the lifetime, for example, 70% of the initial value of the battery capacity.

The broken line in FIG. 8(A) shows that the value of the degradation accelerating parameter K is smaller than that for the standard degradation and the degree of the degradation is small. That is to say, the broken line shows that the lifetime of the secondary battery 28 is longer than that for the standard degradation.

The alternate long and short dash line in FIG. 8(A) shows that the value of the degradation accelerating parameter K is larger than that for the standard degradation and the degree of the degradation is large. That is to say, the alternate long and short dash line shows that the lifetime of the secondary battery 28 is shorter than that for the standard degradation.

On the other hand, FIG. 8(B) shows a result of the lifetime prediction based on a change of the internal resistance (hereinafter, referred to as a “resistance change”) of the secondary battery 28. The resistance change AR is calculated by the following Formula (12), where R represents an initial value of the internal resistance of the secondary battery 28. The internal resistance of the secondary battery 28 increases as the secondary battery 28 degrades.

### {Formula 12}

ΔR=K′·R (12)

In FIG. 8(B), the full line shows a case that the peak values of the history distributions accord with the peak values of the ideal distributions, namely, a case that the deviation amount ΔP_{I2}=1; the deviation amount ΔP_{SOC}=1; the deviation amount ΔP_{T}=1; and the degradation accelerating parameter K′=α′+β′+γ′, (a standard degradation). In the embodiment, the lifetime of the secondary battery 28 is defined as the number of years after which the resistance change will reach a judgment value. The judgment value is a value by which the resistance change is judged to reach the end of the lifetime, for example, 200% of the initial value of the internal resistance.

The broken line in FIG. 8(B) shows that the value of the degradation accelerating parameter K′ is smaller than that for the standard degradation and the degree of the degradation is small. That is to say, the broken line shows that the lifetime of the secondary battery 28 is longer than that for the standard degradation.

The alternate long and short dash line in FIG. 8(B) shows that the value of the degradation accelerating parameter K′ is larger than that for the standard degradation and the degree of the degradation is large. That is to say, the alternate long and short dash line shows that the lifetime of the secondary battery 28 is shorter than that for the standard degradation.

In this stage, the lifetime of the secondary battery 28 is predicted from the respective numbers of years after which the capacity change and the resistance change will reach the judgment values. In the embodiment, for example, the earlier one of the respective numbers of years after which the capacity change and the resistance change will reach the judgment values, is adopted as a predicted lifetime. Then, the difference between the predicted lifetime and the number of years elapsed from the beginning of use of the secondary battery 28, is calculated as a remaining lifetime.

In the subsequent stage 106, the predicted lifetime (in the embodiment, the remaining lifetime) is notified through the superordinate control device 14 on the display device 16. Also, in this stage, if at least one of the degradation accelerating parameters K and K′ derived in stage 102 exceeds a predetermined value showing a large-degree degradation of the secondary battery 28, (for example, twice the degradation accelerating parameter for the case that the deviation amount ΔP_{I2}=1; ΔP_{SOC}=1; and ΔP_{T}=1), a notice showing a large-degree degradation of the secondary battery 28 is displayed on the display device 16 along with the remaining lifetime of the secondary battery 28. Thereafter, this program exits.

In the battery system 10 according to the embodiment, the superordinate control device 14 receives from the BMU 42 each of the values derived in the secondary battery lifetime prediction processing, (for example, the deviation amounts ΔP_{I2}, ΔP_{SOC} and ΔP_{T}), and controls use conditions of the secondary battery 28 such that the deviation amounts between the peak values of the history distributions and the peak values of the ideal distributions become small.

As a concrete example, if the deviation amount ΔP_{I2} for electric current reaches a predetermined value more than 1, that is, if the secondary battery 28 is used with a large electric current at a high frequency, the superordinate control device 14 changes the use range of the electric current, for example, from −300 A to +300 A into −200 A to +200 A, and thereby controls the electric current of the secondary battery 28 such that the deviation amount ΔP_{I2} for electric current becomes small. As another concrete example, if the deviation amount ΔP_{SOC} for stored charge amount reaches a predetermined value less than 1, that is, if the secondary battery 28 is used with a small stored charge amount at a high frequency, the superordinate control device 14 changes the use range of the stored charge amount, for example, from 40% to 60% into 30% to 70%, and thereby controls the stored charge amount of the secondary battery 28 such that the deviation amount ΔP_{SOC} for stored charge amount becomes small.

Thus, the degree of the degradation of the secondary battery 28 comes close to the standard degradation, which is an ideal degradation. This facilitates the management of the lifetime of the secondary battery 28, and thereby facilitates the reuse of the secondary battery 28, for example.

As described above, the battery system 10 according to the embodiment includes the secondary batteries 28 that supply power to the electric current load 18, and the ammeters 32 and thermometers 34 that measure the level of the factors affecting the degradation of the secondary batteries 28, compares the peak values of the history distributions based on the use frequencies of the secondary batteries 28 depending on the level of the factors that are measured multiple times in the predetermined period by the ammeters 32 and the thermometers 34 with the peak values of the ideal distributions based on the previously estimated use frequencies of the secondary batteries 28 depending on the level of the factors, derives the degrees of the degradation of the secondary batteries 28 in use based on the comparison results and the previously estimated degrees of the degradation of the secondary batteries 28, and predicts the lifetime of the secondary batteries 28 based on the degrees of the degradation derived. Thereby, the battery system 10 according to the embodiment allows a more accurate lifetime prediction for the secondary battery.

So far, the present invention has been described with the above embodiment. However, the technical scope of the present invention is not limited to the scope of the description of the above embodiment. Various changes or modifications may be made to the above embodiment without departing from the scope of the present invention, and the changed or modified modes also fall within the technical scope of the present invention.

For example, the above described embodiment adopts the mode in which the battery system 10 includes the BMU 42 and the CMUs 40A, 40B. However, the present invention is not limited to this mode, and may adopt a mode in which the battery system 10 does not include the CMUs 40A, 40B, but the BMU 42 has the functions of the CMUs 40A, 40B.

Also, the above described embodiment adopts the mode in which the lifetime of the secondary battery 28 is predicted from the deviation amount between the peak values of the history distribution and ideal distribution of the use frequency of the secondary battery 28. However, the present invention is not limited to this mode, and may adopt a mode in which the lifetime of the secondary battery 28 is predicted from the deviation amount between the average values of the history distribution and ideal distribution of the use frequency of the secondary battery 28.

In such a mode, the average value of the history distribution and the average value of the ideal distribution are determined, for example, by means of dividing the product between the level of the factor and the use frequency by the number of times of the factor measurement. Thereby, for example, when there are two or more peaks in the history distribution, it is possible to easily determine the deviation amount between the history distribution and the ideal distribution.

Furthermore, the above described embodiment adopts the mode in which the battery system 10 includes the BMU 42 and the CMUs 40A, 40B. However, the present invention is not limited to this mode, and may adopt a mode in which the battery system 10 does not include the CMUs 40A, 40B, but the BMU 42 has the functions of the CMUs 40A, 40B.

Also, the above described embodiment adopts the mode in which the lifetime of the secondary battery 28 is predicted using the electric current, stored charge amount and temperature of the secondary battery 28 as the factors affecting the degradation of the secondary battery 28. However, the present invention is not limited to this mode, and may adopt a mode in which the lifetime of the secondary battery 28 is predicted using at least one of the electric current, stored charge amount and temperature of the secondary battery 28 as the factor affecting the degradation of the secondary battery 28.

In addition, the above described embodiment adopts the mode in which the lifetime of the secondary battery 28 is predicted from both the change in the battery capacity of the secondary battery 28 and the change in the internal resistance of the secondary battery 28. However, the present invention is not limited to this mode, and may adopt a mode in which the lifetime of the secondary battery 28 is predicted from the change in the battery capacity of the secondary battery 28, or the change in the internal resistance of the secondary battery 28.

### REFERENCE SIGNS LIST

10 battery system
14 superordinate control device
28 secondary battery
30 voltmeter
32 ammeter
42 BMU

1. A secondary battery lifetime prediction apparatus comprising:
a measuring section for measuring level of a factor, the factor affecting degradation of a secondary battery;
a comparing section for comparing a first value based on a use frequency of the secondary battery depending on the level of the factor measured by the measuring section with a second value based on a previously estimated use frequency of the secondary battery depending on the level of the factor, the level of the factor being measured multiple times in a predetermined period by the measuring section;
a deriving section for deriving a degree of the degradation of the secondary battery in use, based on a comparison result by the comparing section and a previously estimated degree of the degradation of the secondary battery; and
a predicting section for predicting a lifetime of the secondary battery, based on the degree derived by the deriving section.

2. The secondary battery lifetime prediction apparatus according to claim 1, wherein the deriving section derives the degree of the degradation of the secondary battery in such a manner that the degree of the degradation becomes larger in response to a frequency at which the level of the factor measured by the measuring section exceeds a predetermined threshold.

3. The secondary battery lifetime prediction apparatus according to claim 1, further comprising a control section for controlling a use condition of the secondary battery such that a deviation amount between the first value and the second value becomes small.

4. The secondary battery lifetime prediction apparatus according to claim 1, wherein the deriving section derives the degree of the degradation of the secondary battery in use by multiplying the previously estimated degree of the degradation and the deviation amount between the first value and the second value.

5. The secondary battery lifetime prediction apparatus according to claim 1, wherein the predicting section predicts the lifetime of the secondary battery from at least one of a change in battery capacity of the secondary battery and a change in internal resistance of the secondary battery, the change in the battery capacity and the change in the internal resistance being based on the degree derived by the deriving section.

6. The secondary battery lifetime prediction apparatus according to claim 1, wherein the factor is at least one of electric current of the secondary battery, stored charge amount of the secondary battery and temperature of the secondary battery.

7. A battery system comprising:
a secondary battery supplying power to a load; and
the secondary battery lifetime prediction apparatus according to claim 1 that predicts the lifetime of the secondary battery.

8. A secondary battery lifetime prediction method comprising:
a first stage of comparing a first value based on a use frequency of a secondary battery depending on level of a factor measured by a measuring section with a second value based on a previously estimated use frequency of the secondary battery depending on the level of the factor, the factor affecting degradation of the secondary battery, the level of the factor being measured multiple times in a predetermined period by the measuring section;
a second stage of deriving a degree of the degradation of the secondary battery in use, based on a comparison result by the first stage and a previously estimated degree of the degradation of the secondary battery; and
a third stage of predicting a lifetime of the secondary battery, based on the degree derived by the second stage.
